(19) United States
(12) Patent Application Publication
(10) Pub. No.: US 2011/0174776 A1
(43) Pub. Date: Jul. 21, 2011

(54) PLASMA PROCESSING APPARATUS, PLASMA PROCESSING METHOD AND END POINT DETECTION METHOD

(75) Inventors: Yoshiro Kabe, Hyogo-ken (JP); Kinya Ota, Hyogo-ken (JP); Junichi Kitagawa, Hyogo-ken (JP)

(73) Assignee: Tokyo Electron Limited, Tokyo-To (JP)

(21) Appl. No.: 12/675,019

(22) PCT Filed: Aug. 26, 2008
(86) PCT No.: PCT/JP2008/065206

§ 371 Date: Apr. 6, 2011

(30) Foreign Application Priority Data
Aug. 28, 2007 (JP) 2007-220549

(51) Int. Cl. C23F 1/08; C23F 1/00; C23C 16/455; C23C 16/511; C23C 16/52

(52) U.S. Cl. 216/59; 156/345.25; 118/690; 427/569; 427/575

(57) ABSTRACT

A plasma processing apparatus (100) includes: a plasma generation means for generating a plasma in a processing chamber (1); a measurement section (60) for measuring an integrated value of the particle number of an active species contained in the plasma and moving toward a processing object (wafer W); and a control section (50) for controlling the apparatus in such a manner as to terminate plasma processing when the measured integrated value has reached a set value. The measurement section (60) measures the particle number of the active species by emitting a predetermined laser light from a light source section (61) toward the plasma, and receiving the laser light in a detection section (63) provided with a VUV monochromator.

### TECHNICAL FIELD

The present invention relates to a plasma processing apparatus and a plasma processing method for processing a processing object by using a plasma, and to a method for detecting the end point of plasma processing.

### BACKGROUND ART

Plasma processing is known which performs oxidation, nitridation, etc. of a processing object, such as a semiconductor wafer, by using a plasma. Plasma processing is capable of processing at a low temperature, such as about 400° C., and therefore has an advantage over thermal oxidation processing or the like in that thermal budget can be reduced, thereby suppressing thermal strain, etc. of a semiconductor wafer.

A problem in plasma processing is difficulty in determining its end point precisely. It is a conventional practice in plasma processing to set a processing time based on the rate of processing (e.g. oxidation rate, nitridation rate or etching rate) in advance, and terminate the plasma processing by time control. However, with reference to a plasma, the amount and type of active species, such as radicals and ions, will vary depending on the plasma generation conditions. There could therefore be variation in the results of processing when the processing is terminated merely by time control. In order to solve the problem, Japanese Patent Laid-Open Publication No. 2005-79289, for example, has proposed a technique in which a film thickness monitoring device using an optical method is provided in a chamber to detect the end point of etching. Further, Japanese Patent Laid-Open Publication No. 2002-57149 has proposed a technique which detects the end point of cleaning by monitoring plasma emission.

The technique proposed in Japanese Patent Laid-Open Publication No. 2005-79289 involves measuring the thickness of a remaining film as an etching object to detect the end point of plasma processing, and thus enables real-time monitoring. However, because the measuring object is the thickness of a film, it is difficult to apply this method to end point detection in processing other than etching, such as plasma oxidation or plasma nitridation. The technique proposed in Japanese Patent Laid-Open Publication No. 2002-57149 utilizes change in the chemical composition in the chamber with the progress of cleaning. It is therefore difficult to apply this technique to plasma oxidation or plasma nitridation. Thus, the end point detection methods, proposed in the prior art, each can be applied only to a particular limited processing. End point control based on a plasma processing time is therefore still practiced widely while knowing the possibility of variation in the results of processing depending on the state of plasma.

### DISCLOSURE OF THE INVENTION

The present invention has been made in view of the above situation. It is therefore an object of the present invention to detect the end point of plasma processing with high precision.

According to a first aspect of the present invention, there is provided a plasma processing apparatus comprising: a processing chamber for carrying out plasma processing of a processing object; a plasma generation means for generating a plasma in the processing chamber; a measurement means for measuring an integrated value of the particle number of an active species contained in the plasma and moving toward the processing object; and a control means for controlling the operation of the plasma processing apparatus in such a manner as to terminate the plasma processing when the integrated value has reached a set value.

In the plasma processing apparatus according to the first aspect of the present invention, the active species may be an O(¹D₂) radical as an active oxidizing species. The measurement means may include a light source section for emitting a laser light toward the plasma, and a detection section for detecting the laser light that has passed through the plasma, the light source section and the detection section being disposed such that the light path of the laser light, traveling from the light source section to the detection section, lies in the vicinity of the processing object disposed in the processing chamber. The plasma generation means may include a plane antenna, having a plurality of slots, for introducing microwaves into the processing chamber.

According to a second aspect of the present invention, there is provided a plasma processing method for carrying out plasma processing of a processing object in a processing chamber of a plasma processing apparatus, said method comprising the steps of: generating a plasma in the processing chamber and initiating plasma processing; measuring an integrated value of the particle number of an active species contained in the plasma and moving toward the processing object; and terminating the plasma processing when the integrated value has reached a set value.

In the plasma processing method according to the second aspect of the present invention, the active species may be an O(¹D₂) radical as an active oxidizing species. The active species may be one which is generated in an upper space in the processing chamber and moves downward toward the processing object, and the measurement of the active species may be carried out in the vicinity of the processing object. The plasma processing apparatus may be of the type that introduces microwaves into the processing chamber by means of a plane antenna having a plurality of slots.

According to a third aspect of the present invention, there is provided an end point detection method for detecting the end point of plasma processing of a processing object as carried out in a processing chamber of a plasma processing apparatus, said method comprising the steps of: generating a plasma in the processing chamber and initiating plasma processing; measuring an integrated value of the particle number of an active species contained in the plasma and moving toward the processing object; and detecting the end point of the plasma processing based on a determination as to whether the integrated value has reached a set value.

In the end point detection method according to the third aspect of the present invention, the active species may be an O(¹D₂) radical as an active oxidizing species. The active species may be one which is generated in an upper space in the processing chamber and moves downward toward the processing object, and the measurement of the active species may be carried out in the vicinity of the processing object. The plasma processing apparatus may be of the type that introduces microwaves into the processing chamber by means of a plane antenna having a plurality of slots.

According to a fourth aspect of the present invention, there is provided a computer-readable storage medium in which is stored a control program which operates on a computer, said control program, upon its execution, controlling a plasma processing apparatus such that it carries out an end point detection method for detecting the end point of plasma processing of a processing object as carried out in a processing chamber of the plasma processing apparatus, said end point detection method comprising the steps of: generating a plasma in the processing chamber and initiating plasma processing; measuring an integrated value of the particle number of an active species contained in the plasma and moving toward the processing object; and detecting the end point of the plasma processing based on a determination as to whether the integrated value has reached a set value.

According to a fifth aspect of the present invention, there is provided a plasma processing apparatus comprising: a processing chamber for processing a processing object by using a plasma; a plane antenna, having a plurality of slots, for introducing microwaves into the processing chamber; a gas supply mechanism for supplying a gas into the processing chamber; an exhaust mechanism for evacuating and depressurizing the processing chamber; and a control section for controlling the operation of the plasma processing apparatus such that it carries out an end point detection method for detecting the end point of plasma processing of the processing object as carried out in the processing chamber, said end point detection method comprising the steps of: generating a plasma in the processing chamber and initiating plasma processing; measuring an integrated value of the particle number of an active species contained in the plasma and moving toward the processing object; and detecting the end point of the plasma processing based on a determination as to whether the integrated value has reached a set value.

According to the present invention, the end point of plasma processing can be detected with high precision by measuring an integrated value of the particle number of a particular active species contained in a plasma and moving toward a processing object. Accordingly, by terminating the plasma processing at a point in time when the integrated value reaches a set value, the intended processing can be securely completed without being influenced by the plasma generation conditions or the state of plasma and, in addition, processing uniformity among wafers and lots can be ensured.

The method of the present invention detects the end point of plasma processing by using, as an index, an integrated value of the particle number of an active species. Therefore, compared to the method which manages plasma processing based on time, the method of the present invention can perform more direct and precise end point detection without being influenced by the state of plasma. When compared with the conventional methods which use the thickness of a processing object film or plasma emission as an index in carrying out end point detection, the method of the present invention has the advantage of being applicable to a wider range of plasma processings. Thus, by using the method of the present invention, it becomes possible to precisely and securely perform end point detection in various plasma processings, such as plasma oxidation, plasma nitridation, plasma etching and plasma cleaning.

### BRIEF DESCRIPTION OF THE DRAWINGS

FIG. 1 is a schematic cross-sectional diagram showing an exemplary plasma processing apparatus according to an embodiment of the present invention;

FIG. 2 is a diagram showing the structure of a plane antenna for use in the plasma processing apparatus of FIG. 1;

FIG. 3 is a block diagram illustrating the schematic construction of the control system of the plasma processing apparatus of FIG. 1;

FIG. 4 is a flow chart illustrating an exemplary process of a plasma oxidation method according to an embodiment of the present invention;

FIG. 5 is a flow chart illustrating an exemplary process of an end point detection method according to an embodiment of the present invention; and

FIG. 6 is a graph showing the relationship between the thickness of a silicon oxide film and the fluxes of O(¹D₂) radicals and O(³P₂) radicals in a plasma in plasma oxidation processing.

### BEST MODE FOR CARRYING OUT THE INVENTION

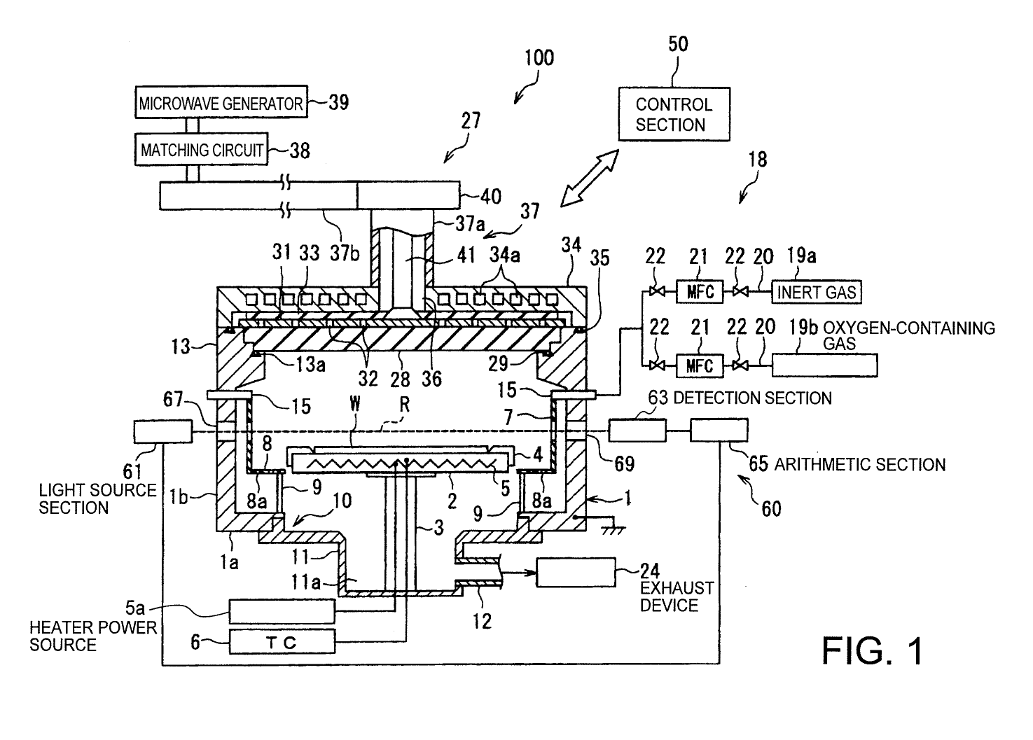

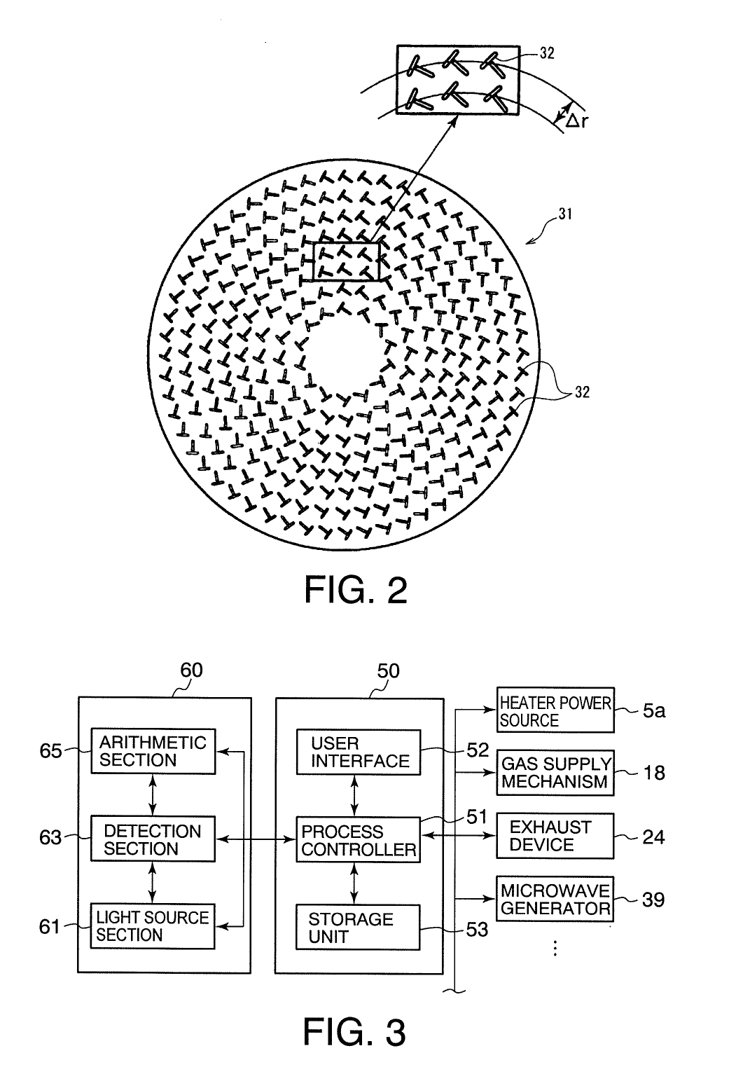

Preferred embodiments of the present invention will now be described in detail with reference to the drawings. The following description illustrates, by way of example, oxidation processing of a processing object by means of a plasma. FIG. 1 is a cross-sectional diagram schematically showing the construction of a plasma processing apparatus 100 according to a first embodiment of the present invention. FIG. 2 is a plan view of the plane antenna of the plasma processing apparatus 100 of FIG. 1. FIG. 3 is a diagram illustrating the schematic construction of the control system of the plasma processing apparatus of FIG. 1.

The plasma processing apparatus 100 is constructed as an RLSA microwave plasma processing apparatus capable of generating a high-density, low-electron temperature, microwave-excited plasma by introducing microwaves into a processing chamber by means of an RLSA (radial line slot antenna), which is a plane antenna having a plurality of slots which are through holes. The plasma processing apparatus 100 can perform processing with a plasma having a plasma density of 1×10¹⁰ to 5×10¹²/cm³ and a low electron temperature of 0.7 to 2 eV (not more than 1 eV in the vicinity of a processing object). The plasma processing apparatus 100 can therefore be advantageously used for oxidizing silicon to form a silicon oxide film in the manufacturing of a variety of semiconductor devices.

The plasma processing apparatus 100 comprises the following main components: an airtight chamber (processing chamber) 1; a gas supply mechanism 18 for supplying a gas into the chamber 1; an exhaust device 24 as an exhaust mechanism for evacuating and depressurizing the chamber 1; a microwave introduction mechanism 27, provided above the chamber 1, for introducing microwaves into the chamber 1; a control section 50 as a control means for controlling these components of the plasma processing apparatus 100; and a measurement section 60 as a measurement means for measuring an integrated value of the particle number of an active species in a plasma. The gas supply mechanism 18, the evacuation device 24 and the microwave introduction mechanism 27 constitute a plasma generation means for generating a plasma in the chamber 1.

The chamber 1 is a grounded, generally-cylindrical container. The chamber 1 may be a container of a rectangular cylinder shape. The chamber 1 has a bottom wall 1a and a side wall 1b, e.g. made of aluminum.

In the chamber 1 is provided a stage 2 for horizontally supporting a silicon wafer (hereinafter referred to simply as “wafer”) W as a processing object. The stage 2 is made of a material having high thermal conductivity, for example, a ceramic material such as AlN. The stage 2 is supported by a cylindrical support member 3 extending upwardly from the center of the bottom of an exhaust chamber 11. The support member 3 is made of e.g. a ceramic material such as AlN.

The stage 2 is provided with a cover ring 4 for covering a peripheral portion of the stage 2 and guiding the wafer W. The cover ring 4 is an annular member made of e.g. quartz, AlN, Al₂O₃ or SiN.

A resistance heating-type heater 5 as a temperature adjustment mechanism is embedded in the stage 2. The heater 5, when powered from a heater power source 5a, heats the stage 2 and, by the heat, uniformly heats the wafer W as a processing substrate.

The stage 2 is provided with a thermocouple (TC) 6. The heating temperature of the wafer W can be controlled e.g. in the range of room temperature to 900° C. by measuring the temperature with the thermocouple 6.

The stage 2 has wafer support pins (not shown) for raising and lowering the wafer W while supporting it. The wafer support pins are each projectable and retractable with respect to the surface of the stage 2.

A cylindrical quarts liner 7 is provided on the inner circumference of the chamber 1. Further, an annular quartz baffle plate 8, having a large number of exhaust holes 8a for uniformly evacuating the chamber 1, is provided around the circumference of the stage 2. The baffle plate 8 is supported on support posts 9.

A circular opening 10 is formed generally centrally in the bottom wall is of the chamber 1. The bottom wall 1a is provided with a downwardly-projecting exhaust chamber 11 which communicates with the opening 10. An exhaust pipe 12 is connected to the exhaust chamber 11, and the exhaust chamber 11 is connected via the exhaust pipe 12 to the exhaust device 24.

An annular upper plate 13 is joined to the upper end of the side wall 1b of the chamber 1. The inner circumference of the plate 13, in the lower portion, projects inwardly (toward the inner space of the chamber), forming an annular support portion 13a.

The side wall 1b of the chamber 1 is provided with an annular gas introduction section 15. The gas introduction section 15 is connected to a gas supply mechanism 18 for supplying an oxygen-containing gas and a plasma excitation gas. It is also possible to construct the gas introduction section 15 in the shape of a nozzle or a shower head.

The side wall 1b of the chamber 1 is also provided with a transfer port (not shown) for transferring the wafer W between the plasma processing apparatus 100 and an adjacent transfer chamber (not shown), and a gate valve (not shown) for opening and closing the transfer port.

The gas supply mechanism 18 has, for example, an inert gas supply source 19a and an oxygen-containing gas (O-containing gas) supply source 19b. The gas supply mechanism 18 may also have a not-shown gas supply source(s) other than the above sources, for example, a supply source for hydrogen gas which is mixed with oxygen gas in order to increase the oxidation rate, a supply source for a purge gas to be used for replacement of the atmosphere in the chamber, or a supply source for a cleaning gas to be used for cleaning of the interior of the chamber 1.

N₂ gas or a rare gas, for example, can be used as an inert gas. Examples of usable rare gases include Ar gas, Kr gas, Xe gas and He gas. Oxygen (O₂) gas, for example, can be used as an oxygen-containing gas.

An inert gas and an oxygen-containing gas, respectively from the inert gas supply source 19a and the oxygen-containing gas supply source 19b of the gas supply mechanism 18, each pass through a respective gas line 20 and reach the gas introduction section 15, and is introduced from the gas introduction section 15 into the chamber 1. The respective gas line 20 connected to each gas supply source is provided with a mass flow controller 21 and on-off valves 22 located upstream and downstream of the controller 21. Such construction of the gas supply mechanism 18 enables switching of the gases supplied and control of the flow rate of each gas, etc.

The exhaust device 24 as an exhaust mechanism includes a high-speed vacuum pump, such as a turbo-molecular pump. As described above, the exhaust device 24 is connected via the exhaust pipe 12 to the exhaust chamber 11 of the chamber 1. By the actuation of the exhaust device 24, the gas in the chamber 1 uniformly flows into the space 11a of the exhaust chamber 11, and is discharged from the space 11a through the exhaust pipe 12 to the outside. The chamber 1 can thus be rapidly depressurized into a predetermined vacuum level, e.g. 0.133 Pa.

The construction of the microwave introduction mechanism 27 will now be described. The microwave introduction mechanism 27 mainly comprises a transmissive plate 28, a plane antenna 31, a retardation member 33, a shield cover 34, a waveguide 37, a matching circuit 38 and a microwave generator 39.

The transmissive plate 28, which is transmissive to microwaves, is supported on the inwardly-projecting support portion 13a of the upper plate 13. The transmissive plate 28 is composed of a dielectric material, for example, a ceramic material such as quartz, Al₂O₃, AlN, etc. The transmissive plate 28 and the support portion 13a are hermetically sealed with a seal member 29, so that the chamber 1 is kept hermetic.

The plane antenna 31 is provided over the transmissive plate 28 such that it faces the stage 2. The plane antenna 13 is locked into the upper end of the upper plate 13. The plane antenna 31 has a disk-like shape. The shape of the plane antenna 31 is not limited to a disk-like shape: for example, the antenna may be of a square plate-like shape.

The plane antenna 31 is comprised of e.g. a copper plate or a nickel plate, whose surface is plated with gold or silver. The plane antenna 31 has a large number of slots 32 that radiate microwaves. The slots 32, which penetrate the plane antenna 31, are formed in a predetermined pattern.

Each slot 32 is a narrow opening as shown in FIG. 2, and adjacent two slots 32 are paired typically in a letter “T” arrangement. The slots 32, comprised of such pairs in a predetermined arrangement (e.g. letter “T” arrangement), are arranged in concentric circles as a whole.

The length of the slots 32 and the spacing in their arrangement are determined depending on the wavelength (λg) of microwaves. For example, the slots 32 are arranged with a spacing of λg/4, λg/2 or λg. In FIG. 2, the spacing between adjacent concentric lines of slots 32 is denoted by Δr. The slots 32 may have other shapes, such as a rectangular shape, a circular shape and an arch shape. The arrangement of the slots 32 is not limited to the concentric arrangement: the slots 32 may be arranged e.g. in a spiral or radial arrangement.

The retardation member 33, made of a material having a higher dielectric constant than vacuum, for example, quartz or a resin such as polytetrafluoroethylene or polyimide, is provided on the upper surface of the plane antenna 31. The retardation member 33 is employed in consideration of the fact that the wavelength of microwaves becomes longer in vacuum. The retardation member 33 functions to shorten the wavelength of microwaves, thereby adjusting a plasma.

The plane antenna 31 and the transmissive plate 28, and the retardation member 33 and the plane antenna 31 may be in contact with or spaced apart from each other, though preferably be in contact with each other.

The shield cover 34 is provided over the chamber 1 such that it covers the plane antenna 31 and the retardation member 33. The shield cover 34 is formed of a metal material such as aluminum or stainless steel. The upper end of the upper plate 13 and the shield cover 34 are sealed with a seal member 35. A cooling water flow passage 34a is formed in the interior of the shield cover 34. The shield cover 34, the retardation member 33, the plane antenna 31 and the transmissive plate 28 can be cooled by passing cooling water through the cooling water flow passage 34a. The shield cover 34 is grounded.

An opening 36 is formed in the center of the upper wall (ceiling) of the shield cover 34, and the waveguide 37 is connected to the opening 36. The other end of the waveguide 37 is connected via the matching circuit 38 to the microwave generator 39.

The waveguide 37 is comprised of a coaxial waveguide 37a having a circular cross-section and extending upward from the opening 36 of the shield cover 34, and a horizontally-extending rectangular waveguide 37b connected via a mode converter 40 to the upper end of the coaxial waveguide 37a. The mode converter 40 functions to convert microwaves, propagating in TE mode through the rectangular waveguide 37b, into TEM mode microwaves.

An inner conductor 41 extends centrally in the coaxial waveguide 37a. The inner conductor 41, at its lower end, is connected and secured to the center of the plane antenna 31. With such construction, microwaves are propagated through the inner conductor 41 of the coaxial waveguide 37a to the plane antenna 31 radially, efficiently and uniformly.

With the microwave introduction mechanism 27 thus constructed, microwaves generated in the microwave generator 39 are propagated through the waveguide 37 to the plane antenna 31, and introduced through the transmissive plate 28 into the chamber 1. An exemplary microwave frequency which is preferably used is 2.45 GHz. Other frequencies such as 8.35 GHz and 1.98 GHz can also be used.

As shown in FIG. 3, the measurement section 60 includes a light source section 61 for emitting a predetermined laser light toward a plasma, a detection section 63, provided with a monochromator (not shown), for receiving the laser light that has passed through the plasma, and an arithmetic section 65 for calculating the particle number of a radical by numerical analysis of the results of detection in the detection section 63, and integrating the calculated values. A VUV monochromator is used as the monochromator. In this embodiment the measurement section 60 measures an O(¹D₂) radical, one of active oxidizing species in a plasma.

The light source section 61 (the detailed structure thereof is not shown in the drawing) has, for example, an XeCl excimer laser that oscillates a laser light having a wavelength of 308 nm, and a plurality of dye lasers that oscillate a light having a predetermined wavelength using the XeCl excimer laser as a pump light. Besides the VUV monochromator, the detection section 63 is provided with a not-shown photomultiplier tube (PMT) for converting wavelength data, detected by the VUV monochromator, into electrical signals. Though not shown diagrammatically, the arithmetic section 65 includes an arithmetic means such as a CPU, a memory means such as a RAM, and a particle number counter for performing sequential and cumulative addition of the particle number. The measurement section 60 is connected to a process controller 51 of the control section 50.

As shown in FIG. 1, the light source 61 is disposed outside the chamber, and the detection section 63 is disposed outside the chamber and on the opposite side of the chamber from the light source section. The laser light emitted from the light source section 61 is introduced through a transmissive window 67, provided in the side wall of the chamber 1, into the chamber 1. The laser light then passes through a plasma space in the chamber 1, then passes though a transmissive window 69, provided in the side wall of the chamber 1 at a position opposite the transmissive window 67, and comes out of the chamber 1, and is received by the detection section 63.

In measurement of a microwave plasma by means of the measurement section 60, a light path R along which the laser light travels from the light source section 61 to the detection section 63 may be provided such that it traverses the plasma. Preferably, the light path R runs above and close to the wafer W as a processing object, for example, 1 to 10 mm above the surface of the wafer W. Thus, it is preferred that the distance between the wafer receiving surface of the stage 2 and the light path R be in the range of about 1.5 to 12 mm. Some of O(¹D₂) radicals present in the plasma become deactivated on their way to the wafer W. Accordingly, the larger the distance between the light path R, which is the measurement position, and the wafer W is, the lower is the correlation between the particle number of O(¹D₂) radicals present on the light path R and the particle number of those radicals which actually reach the wafer W, making it more difficult to obtain accurate measurement results. Thus, by setting the position of the light path R, i.e. the measurement position, in the vicinity of the wafer W, the number of O(¹D₂) radicals which actually reach the wafer W and contribute to oxidation can be determined more precisely.

The measurement section 60 can optically measure the density of O(¹D₂) radicals in an oxygen gas plasma, for example by means of vacuum ultraviolet laser absorption spectroscopy using a wavelength-variable vacuum ultraviolet laser. This method involves oscillating a wavelength-variable vacuum ultraviolet laser light, which is near the resonance line of oxygen atom as a measuring object, by using a dye laser and a rare gas cell, allowing the ultraviolet laser light to pass through the plasma as an absorber, and measuring the absorption profile of the laser light and the emission profile of the laser light with a spectroscope and determining the density of O(¹D₂) radicals from the ratio between the absorption and emission values. This measurement method is a non-contact method using a light, and therefore enables real-time in-line measurement without affecting a plasma as a measuring object.

The measurement section 60 can measure radicals other than O(¹D₂), such as an O(³Pⱼ) radical. An O(³Pⱼ) radical, however, is weak in the oxidizing action and little contributes to an oxidation reaction. In plasma oxidation processing carried out by using the plasma processing apparatus 100, the oxidation reaction progresses mainly by O(¹D₂) radicals. In this embodiment, therefore, only the particle number of O(¹D₂) radicals is selectively measured. This can determine the end point of plasma oxidation processing almost precisely.

Measurement of the density of O(¹D₂) radicals, which are active species in a plasma, by means of vacuum ultraviolet laser absorption spectroscopy using a wavelength-variable vacuum ultraviolet laser light, can be carried out e.g. in the following manner: A laser light for detection of O(¹D₂) radicals, having a wavelength of around 115.2 nm, is oscillated by the laser light source of the light source section 61 with a Xe—Ar mixed rare gas as a nonlinear medium, and emitted toward the plasma. Wave lengths in the third harmonic generation process are detected by the VUV monochromator of the detection section 63. The light source section 61 scans the wavelengths of the laser light in the absorption wavelength range for O(¹D₂) radicals as measuring object radicals, and the detection section 63 measures the scanned wavelengths to determine the absorptance at each wavelength. Based on the wavelength dependency of the absorptance and the emission profile of the laser light, the arithmetic section 65 performs analysis to calculate the absolute density of the measuring object radicals. Such radial density measurement method is a known method as described in, for example, Summary Papers of the 53rd Lecture Meeting of the Japan Society of Applied Physics, No. 1, 22p-ZL-1, p. 177, 2006 (Japan). When the absorptance of the laser light is determined, the translational temperature of O(¹D₂) radicals can also be determined by a known method.

When the absolute density n (cm⁻³) and the translational temperature T (K) of O(¹D₂) radicals are determined, the flux Fr (cm⁻²sec⁻¹) of O(¹D₂) radicals, i.e. the number of O(¹D₂) radicals passing through a unit area at the absolute density measurement site per unit time, can be determined by the following formula 1:

Fr=(1/4)·n·(8 kT/nm)^{1/2} (1)

wherein “k” is the Boltzmann constant and “m” is the mass of the radical.

The absorptance of the vacuum ultraviolet laser light emitted from the light source section 61 is measured by the detection section 63. The absolute density n and the translational temperature T of O(¹D₂) radicals are calculated from the measured absorptance by the arithmetic section 65, and the flux of O(¹D₂) radicals is determined by using the above formula 1. The particle number of the radicals can be determined by multiplying the flux by the processing time. More specifically, the flux measurement is carried out repeatedly at predetermined time t intervals (t is, for example, 1 second or shorter). In the particle number counter of the arithmetic section 65, the product of the flux Fr and the predetermined time t (the number of particles that has passed through a unit area during the predetermined time t) is added cumulatively at predetermined time t intervals. The thus-measured integrated value of the particle number of O(¹D₂) radicals is considered to approximate the particle number of O(¹D₂) radicals that has reached the wafer W during the plasma processing. Thus, the plasma processing apparatus 100 can monitor in real time the particle number of O(¹D₂) radicals which is almost equal to the particle number of those radicals which have actually reached the wafer W. The particle number of O(¹D₂) radicals is measured as the particle number per an arbitrary unit area (e.g. per cm²). The particle number counter may therefore integrate the particle numbers per unit area or integrate values, each having been converted into the particle number for the entire surface area of the wafer. A processing termination signal is issued at a point in time when the integrated value reaches a set value. The above flux takes a constant value when the process is stable, and can therefore be used as a real-time process diagnosis monitor.

The components of the plasma processing apparatus 100 are each connected to and controlled by the control section 50. As shown in FIG. 3, the control section 50 includes a process controller 51 provided with a CPU, and a user interface 52 and a storage unit 53, both connected to the process controller 51. The process controller 51 comprehensively controls those components of the plasma processing apparatus 100 which are related to process conditions, such as temperature, gas flow rate, pressure, microwave power, etc. (heater power source 5a, gas supply mechanism 18, exhaust device 24, microwave generator 39, etc.). The process controller 51 of the control section 50 is also connected to the light source section 61, the detection section 63 and the arithmetic section 65 of the measurement section 60, and analyzes plasma data measured by the measurement section 60 and, based on the data, sends out control signals to components of the plasma processing apparatus 100. For example, the process controller 51 can detect the end point of plasma processing by comparing the integrated value of the number of O(¹D₂) radicals, measured by the particle number counter of the arithmetic section 65, with a set value specified in a recipe, and send a command (control signal) to terminate plasma oxidation processing to each end device.

The user interface 52 includes a keyboard for a process manager to perform a command input operation, etc. in order to manage the plasma processing apparatus 100, a display which visualizes and displays the operating situation of the plasma processing apparatus 100, etc. In the storage unit 53 are stored a control program (software) for executing, under control of the process controller 51, various processings to be carried out in the plasma processing apparatus 100, and a recipe in which data on processing conditions, etc. is recorded.

A desired processing is carried out in the chamber 1 of the plasma processing apparatus 100 under the control of the process controller 51 by calling up an arbitrary recipe from the storage unit 53 and causing the process controller 51 to execute the recipe, e.g. through the operation of the user interface 52 performed as necessary. With reference to the process control program and the recipe of processing condition data, etc., it is possible to use those stored in a computer-readable storage medium, such as CD-ROM, hard disk, flexible disk, flash memory, DVD, blu-ray disc, etc. or to transmit them from another device e.g. via a dedicated line as needed, and use them online.

The plasma processing apparatus 100 thus constructed enables plasma processing to be carried out at a low temperature of not more than 800° C., preferably not more than 550° C., without damage to a base film, etc. Further, the plasma processing apparatus 100 is excellent in the uniformity of plasma, and can therefore achieve uniform processing.

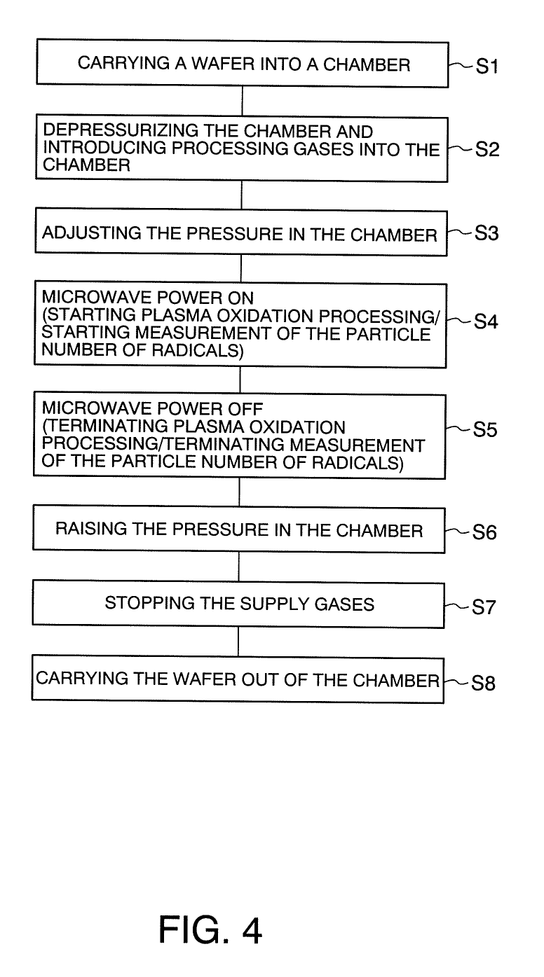

An exemplary plasma oxidation process according to an embodiment of the present invention, carried out by using the plasma processing apparatus of 100, will now be described with reference to FIG. 4. First, a command to carry out plasma oxidation processing in the plasma processing apparatus 100 is inputted by a process manager e.g. through the user interface 52. Upon receipt of the command, the process controller 51 reads out a recipe stored in the storage unit 53. The process controller 51 then sends out, as a command to cause the apparatus to carry out plasma oxidation processing, control signals to end devices such as the gas supply mechanism 18, the exhaust device 24, the microwave generator 39, the heater power source 5a, etc., and also sends out a control signal to the measurement section 60 for it to perform the measurement of the density of radicals.

In step S1, the not-shown gate valve is opened, and a wafer W is carried through the transfer port into the chamber 1 and placed on the stage 2. Next, in step 2, while evacuating and depressurizing the chamber 1 by the actuation of the exhaust device 24, an inert gas and an oxygen-containing gas are supplied from the inert gas supply source 19a and the oxygen-containing gas supply source 19b of the gas supply mechanism 18 and introduced through the gas introduction section 15 into the chamber 1 respectively at a predetermined flow rate. A rare gas, such as Ar, Kr or Xe, is preferably used as the inert gas. In step S3, the pressure in the chamber 1 is adjusted to a predetermined pressure by adjusting the amount of exhaust gas and the amounts of the gases supplied.

Next, in step S4, the microwave power of the microwave generator 39 is turned on to generate microwaves. The microwaves generated, having a predetermined frequency, for example 2.45 GHz, are introduced via the matching circuit 38 into the waveguide 37. The microwaves introduced into the waveguide 37 pass through the rectangular waveguide 37b and then through the coaxial waveguide 37a, and is supplied through the inner conductor 41 to the plane antenna 31. The microwaves propagate in TE mode in the rectangular waveguide 37b. The TE mode microwaves are converted into TEM mode microwaves by the mode converter 40, and the TEM mode microwaves are propagated in the coaxial waveguide 37a toward the plane antenna 31. The microwaves are then radiated from the slots 32 penetrating the plane antenna 31, and introduced through the transmissive plate 28 into the space above the wafer W in the chamber 1. The microwave power density per unit area (cm²) of the transmissive plate 28 may be selected, e.g. within the range of 0.3 to 3 W/cm², in accordance with the purpose.

By the microwaves radiated from the plane antenna 31 into the chamber 1 via the transmissive plate 28, an electromagnetic field is formed in the chamber 1, and the inert gas and the oxygen-containing gas turn into a plasma. Because the microwaves are radiated from the large number of slots 32 of the plane antenna 31, the microwave-excited plasma has a high density of about 1×10¹⁰ to 5×10¹²/cm³ and, in the vicinity of the wafer W, has a low electron temperature of not more than about 1.5 eV. The microwave-excited high-density plasma thus formed causes little damage, e.g. by ions, to a base film. By the action of active species, such as radicals and ions, in the plasma, the silicon surface of the wafer W is oxidized to form a silicon oxide film (SiO₂ film).

In this embodiment, an integrated value of the particle number of O(¹D₂) radicals, active species involved in the oxidation, contained in the plasma and moving toward the wafer W, is measured in real time with the measurement section 60 during the plasma oxidation processing. For this purpose, in step S4, the measurement of O(¹D₂) radicals with the measurement section 60 is started simultaneously with the start of the plasma oxidation processing.

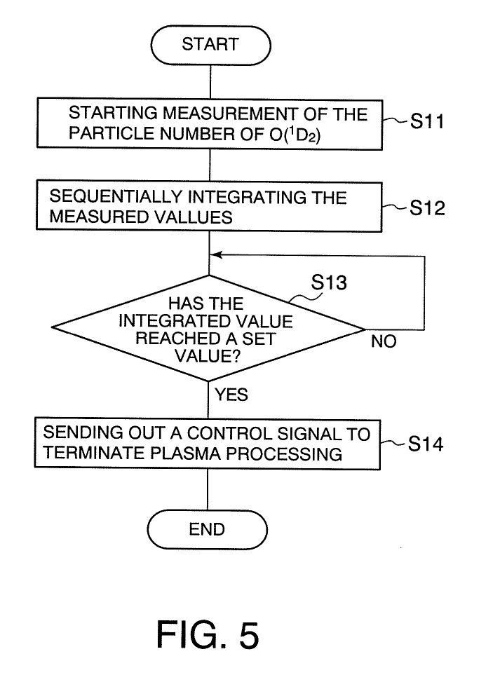

The detection of the end point of plasma oxidation processing based on the measurement of radicals is performed e.g. according to the procedure, consisting of steps S11 to S14, shown in FIG. 5. Upon receipt of a command (control signal) to perform the measurement of the radical density from the process controller 51, the measurement section 60 starts the measurement of the particle number of O(¹D₂) radicals (step S11). In particular, a laser light is emitted from the light source section 61 toward the plasma in the chamber 1, and the laser light that has passed through the plasma is received by the detection section 63; and the particle number of the radicals is measured repeatedly in the above-described manner. The measured particle numbers of O(¹D₂) radicals are integrated (added) by means of the particle number counter (not shown) of the arithmetic section 65 (step S12).

The process controller 51 reads out the latest integrated value from the particle number counter of the arithmetic section 65, and checks the value with a set value specified in a recipe to determine whether the integrated value has reached the set value (step S13). The “set value” can be determined e.g. by preparing a calibration curve from the relationship between a pre-measured integrated value of the particle number of O(¹D₂) radicals and an actually measured thickness of an oxide film. If it is determined that the integrated value has reached the set value (Yes) in step S13, the process controller 51 sends out a command (control signal) to terminate the plasma oxidation processing to each end device (step S14).

On the other hand, if it is determined that the integrated value has not reached the set value (No) in step S13, the process controller 51 reads out a renewed integrated value and checks the value with the set value to determine whether the set value is reached. This operation is repeated during the plasma oxidation processing until the set value is reached.

Referring again to FIG. 4, when a command (control signal) to terminate the plasma oxidation processing is sent out from the process controller 51 upon the integrated value having reached the set value or for other reasons, the microwave power of the microwave generator 39 is turned off in step S5 to terminate the plasma oxidation processing. At the same time, the measurement of the particle number of the radicals is terminated. Next, the pressure in the chamber is raised in step S6, and the supply of the processing gases form the gas supply mechanism 18 is stopped in step S7. In step S8, the wafer W is carried out of the chamber 1, whereby the plasma processing for the one wafer W is completed.

The principle of the plasma processing end point detection according to this embodiment, performed by means of the plasma processing apparatus 100, will now be described. As described above, it is a conventional practice to manage the termination of plasma oxidation processing by time control. However, it has been difficult with the time-based management method to strictly control the thickness of an oxide film formed because of the fact that the oxidation rate varies due to a change in the plasma processing conditions or in the state of plasma and therefore the thickness of an oxide film can vary among wafers despite the same processing time.

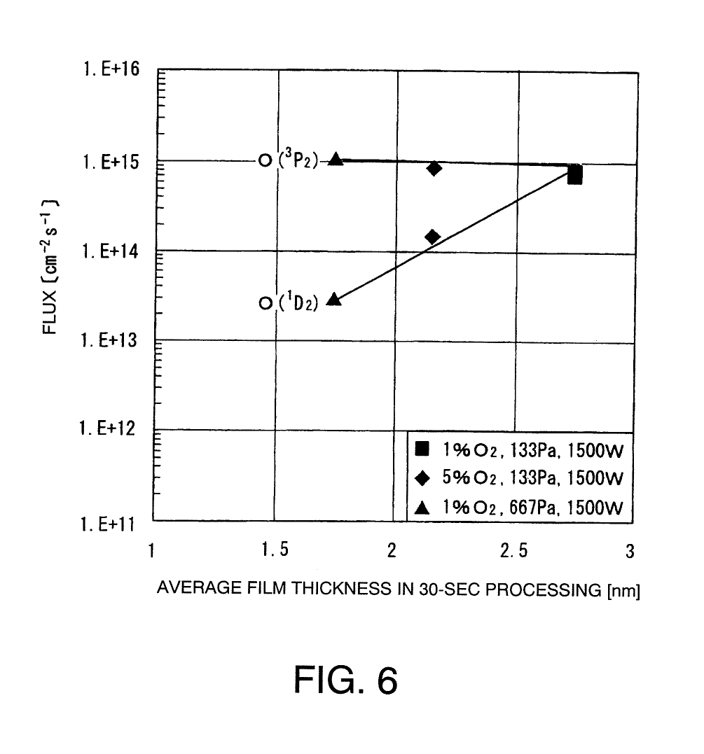

On the other hand, the method of this embodiment uses, instead of processing time, the results of measurement of O(¹D₂) radicals which are active species in a plasma. FIG. 6 shows the relationship between the thickness of a silicon oxide film formed by plasma oxidation processing of a silicon surface of a wafer W, carried out under the below-described conditions 1 to 3 by using the plasma processing apparatus 100, and the fluxes of O(¹D₂) radicals and O(³P₂) radicals, contained in the plasma and moving toward the silicon substrate, measured by means of the measurement section 60. The flux of radicals refers to the particle number of radicals passing through a 1-cm² area per second.

### [Common Conditions]

### Processing gas: Ar and O₂

Processing temperature: 400° C.
Microwave power density (per unit area of the transmissive plate 28): 1.46 W/cm²
Microwave power: 1500 W
Diameter of the transmissive plate 28: 362 mm
Processing time: 30 sec
[Conditions 1] (square mark in FIG. 6)
Ar flow rate: 500 ml/min (sccm)
O₂ flow rate: 5 ml/min (sccm)
O₂/Ar ratio: 1% O₂

### Pressure: 133 Pa

[Conditions 2] (rhombic mark in FIG. 6)
Ar flow rate: 475 ml/min (sccm)
O₂ flow rate: 25 ml/min (sccm)
O₂/Ar ratio: 5% O₂

### Pressure: 133 Pa

[Conditions 3] (triangular mark in FIG. 6)
Ar flow rate: 500 ml/min (sccm)
O₂ flow rate: 5 ml/min (sccm)
O₂/Ar ratio: 1% O₂

### Pressure: 667 Pa

As will be appreciated from the data in FIG. 6, the thickness of the oxide film increases with increase in the flux of O(¹D₂) radicals which are active oxidizing species in the plasma; and there is a direct proportional relationship between the flux and the film thickness. This suggests that the thickness of an oxide film, formed on the surface of a wafer W as a processing object, can be determined if a cumulative total value of the flux of O(¹D₂) radicals (i.e. integrated particle number) moving toward the substrate W can be measured. On the other hand, there is no proportional relationship between the thickness of the oxide film and the flux of O(³P₂) radicals which exist in the plasma together with O(¹D₂) radicals. Thus, it has turned out that when carrying out the measurement of radicals in a plasma, it is important to select and measure an active species which contributes to oxidation reaction.

The present invention has been completed based on the above findings. Thus, by measuring the particle number of O(¹D₂) radicals in a plasma and monitoring the integrated value in real time, and by using separately prepared data (e.g. calibration curve), it becomes possible to determine the thickness of a silicon oxide film being formed. Further, the formation of the silicon oxide film with a target thickness (i.e. the end point of plasma oxidation processing) can be detected at a point in time when the integrated particle number of O(¹D₂) radicals reaches a predetermined value.

Unlike the conventional time-based management method, the end point detection method of this embodiment monitors the particle number of a selected target active species contained in a plasma and which is a main oxidizing species for the intended oxidation, and therefore has the advantage that accurate end point detection is possible even when the state of the plasma has changed for some reason. Accurate end point detection is possible also when the oxidation rate has changed e.g. due to a change made to the plasma oxidation conditions. Thus, the end point detection method of this embodiment makes it possible to facilitate the detection of the end point of plasma oxidation processing and to control the thickness of an oxide film with high precision. According to a plasma oxidation processing method using the end point detection method of this embodiment, a silicon oxide film having a desired thickness can be formed with high precision on the surface of a wafer W and, in addition, the uniformity of the thickness of the oxide film among wafers and lots can be ensured.

While the present invention has been described with reference to preferred embodiments, it is understood that the present invention is not limited to the embodiments, but is capable of various modifications. For example, though plasma oxidation processing, for which O(¹D₂) radicals as active species are measured, has been described by way of example, the end point detection method of the present invention is generally applicable to any plasma processing that is capable of active species measurement. Thus, the end point detection method of the present invention, by selecting an appropriate active species as a measuring object, can be applied to plasma processing other than plasma oxidation, such as plasma nitridation, plasma etching using a CF series gas (CF₄, C₂F₆, C₄F₈, etc.), SF₆, F₂Cl₂, HBr, or the like as an etching gas, plasma cleaning using ClF₃, NF₃, or the like as a cleaning gas, plasma CVD, etc. Further, the present invention is not limited to measurement of a single active species, but is applicable to simultaneous measurement of a plurality of active species.

For example, when the end point detection method of the present invention is applied to end point detection in plasma nitridation processing, a nitrogen radical may be measured as an active species. When the end point detection method of the present invention is applied to end point detection in plasma nitridation/oxidation processing, one or more of a nitrogen radical, an ammonia radical, a nitric oxide radical, etc. may be measured as active species. When the present invention is applied to plasma oxidation processing, active species other than an O(¹D₂) radical, e.g. a hydroxyl radical (OH radical), may also be measured.

1. A plasma processing apparatus comprising:
a processing chamber for carrying out plasma processing of a processing object;
a plasma generation means for generating a plasma in the processing chamber;
a measurement means for measuring an integrated value of the particle number of an active species contained in the plasma and moving toward the processing object; and
a control means for controlling the operation of the plasma processing apparatus in such a manner as to terminate the plasma processing when the integrated value has reached a set value.

2. The plasma processing apparatus according to claim 1, wherein the active species is an O(¹D₂) radical as an active oxidizing species.

3. The plasma processing apparatus according to claim 1, wherein the measurement means includes a light source section for emitting a laser light toward the plasma, and a detection section for detecting the laser light that has passed through the plasma, the light source section and the detection section being disposed such that the light path of the laser light, traveling from the light source section to the detection section, lies in the vicinity of the processing object disposed in the processing chamber.

4. The plasma processing apparatus according to any one of claims 1 to 3, wherein the plasma generation means includes a plane antenna, having a plurality of slots, for introducing microwaves into the processing chamber.

5. A plasma processing method for carrying out plasma processing of a processing object in a processing chamber of a plasma processing apparatus, said method comprising the steps of:
generating a plasma in the processing chamber and initiating plasma processing;
measuring an integrated value of the particle number of an active species contained in the plasma and moving toward the processing object; and
terminating the plasma processing when the integrated value has reached a set value.

6. The plasma processing method according to claim 5, wherein the active species is an O(¹D₂) radical as an active oxidizing species.

7. The plasma processing method according to claim 5, wherein the active species is one which is generated in an upper space in the processing chamber and moves downward toward the processing object, and wherein the measurement of the active species is carried out in the vicinity of the processing object.

8. The plasma processing method according to any one of claims 5 to 7, wherein the plasma processing apparatus is of the type that introduces microwaves into the processing chamber by means of a plane antenna having a plurality of slots.

9. An end point detection method for detecting the end point of plasma processing of a processing object as carried out in a processing chamber of a plasma processing apparatus, said method comprising the steps of:
generating a plasma in the processing chamber and initiating plasma processing;
measuring an integrated value of the particle number of an active species contained in the plasma and moving toward the processing object; and
detecting the end point of the plasma processing based on a determination as to whether the integrated value has reached a set value.

10. The end point detection method according to claim 9, wherein the active species is an O(¹D₂) radical as an active oxidizing species.

11. The end point detection method according to claim 9, wherein the active species is one which is generated in an upper space in the processing chamber and moves downward toward the processing object, and wherein the measurement of the active species is carried out in the vicinity of the processing object.

12. The end point detection method according to any one of claims 9 to 11, wherein the plasma processing apparatus is of the type that introduces microwaves into the processing chamber by means of a plane antenna having a plurality of slots.

13. A computer-readable storage medium in which is stored a control program which operates on a computer, said control program, upon its execution, controlling a plasma processing apparatus such that it carries out an end point detection method for detecting the end point of plasma processing of a processing object as carried out in a processing chamber of the plasma processing apparatus, said end point detection method comprising the steps of: generating a plasma in the processing chamber and initiating plasma processing; measuring an integrated value of the particle number of an active species contained in the plasma and moving toward the processing object; and detecting the end point of the plasma processing based on a determination as to whether the integrated value has reached a set value.

14. A plasma processing apparatus comprising:
a processing chamber for processing a processing object by using a plasma;
a plane antenna, having a plurality of slots, for introducing microwaves into the processing chamber;
a gas supply mechanism for supplying a gas into the processing chamber;
an exhaust mechanism for evacuating and depressurizing the processing chamber; and
a control section for controlling the operation of the plasma processing apparatus such that it carries out an end point detection method for detecting the end point of plasma processing of the processing object as carried out in the processing chamber, said end point detection method comprising the steps of: generating a plasma in the processing chamber and initiating plasma processing; measuring an integrated value of the particle number of an active species contained in the plasma and moving toward the processing object; and detecting the end point of the plasma processing based on a determination as to whether the integrated value has reached a set value.
